(19) United States
(12) Patent Application Publication
(10) Pub. No.: US 2010/0238736 A1
(43) Pub. Date: Sep. 23, 2010

(54) Semiconductor storage device

(75) Inventors: Yoshihiko Kamata, Yokohama-Shi (JP); Jin Kashiwagi, Yokohama-Shi (JP); Hikaru Mochizuki, Yokohama-Shi (JP)

Correspondence Address: POSZ LAW GROUP, PLC, 12040 SOUTH LAKES DRIVE, SUITE 101, RESTON, VA, 20191, US

(73) Assignee: KABUSHIKI KAISHA TOSHIBA, Tokyo (JP)

(21) Appl. No.: 12/659,092

(22) Filed: Feb. 25, 2010

(30) Foreign Application Priority Data
Mar. 17, 2009 (JP) 2009-63882

(51) Int. Cl. G11C 16/06; G11C 5/14; G11C 7/06

(52) U.S. Cl. 365/185.21; 365/189.09; 365/189.07

(57) ABSTRACT

1. A semiconductor storage device has a first MOS transistor connected at a first end thereof to a power supply and diode-connected; a second MOS transistor connected in parallel with the first MOS transistor; a memory cell connected between the second end of the first MOS transistor and ground, the memory cell capable of adjusting a current flowing through the memory cell; a third MOS transistor connected at a first end thereof to the power supply, and diode-connected; a fourth MOS transistor connected in parallel with the third MOS transistor; a fifth MOS transistor connected between the second end of the fourth MOS transistor and the ground and supplied at a gate thereof with the first reference voltage; and an amplifier circuit which compares the sense voltage with the comparison voltage, and which outputs a comparison result signal depending upon a result of the comparison.

### CROSS-REFERENCE TO RELATED APPLICATION

This application is based upon and claims the benefit of priority from the prior Japanese Patent Application No. 2009-63882, filed on Mar. 17, 2009, the entire contents of which are incorporated herein by reference.

### BACKGROUND OF THE INVENTION

1. Field of the Invention

The present invention relates to a semiconductor storage device. In particular, the present invention relates to a semiconductor storage device such as a NOR flash memory and a ReRAM for which sense operation is conducted by changing a resistance value and thereby changing the quantity of a current flowing through a memory cell.

2. Background Art

In some conventional driving semiconductor integrated circuits, the size of a MOS transistor of mirror source which lets a reference current flow is made large or the number of MOS transistors is increased in order to suppress dispersion of the current in the current copy operation (see, for example, Japanese Patent Laid-Open No. 2003-228333 and Japanese Patent Laid-Open No. 2004-271646).

### SUMMARY OF THE INVENTION

According to one aspect of the present invention, there is provided: a semiconductor storage device comprising:

a first reference voltage source which generates a first reference voltage;

a first MOS transistor of a first conductivity type connected at a first end thereof to a power supply and diode-connected;

a second MOS transistor of the first conductivity type connected at a first end thereof to the power supply and connected at a second end thereof to a second end of the first MOS transistor, diode-connected, and connected in parallel with the first MOS transistor, the second MOS transistor having same size as the first MOS transistor does;

a memory cell connected between the second end of the first MOS transistor and ground, the memory cell capable of adjusting a current flowing through the memory cell;

a third MOS transistor of the first conductivity type connected at a first end thereof to the power supply, and diode-connected, the third MOS transistor having same size as the first MOS transistor does;

a fourth MOS transistor of the first conductivity type connected at a first end thereof to the power supply, connected at a second end thereof to a second end of the third MOS transistor, diode-connected, and connected in parallel with the third MOS transistor, the fourth MOS transistor having same size as the third MOS transistor does;

a fifth MOS transistor of a second conductivity type connected between the second end of the fourth MOS transistor and the ground and supplied at a gate thereof with the first reference voltage; and

an amplifier circuit which is supplied with a sense voltage at the second end of the first MOS transistor and a comparison voltage at the second end of the third MOS transistor, which compares the sense voltage with the comparison voltage, and which outputs a comparison result signal depending upon a result of the comparison.

According to another aspect of the present invention, there is provided: a semiconductor storage device comprising:

a first reference voltage source which generates a first reference voltage;

a second reference voltage source which generates a second reference voltage which is lower than the first reference voltage;

a first MOS transistor of a first conductivity type connected at a first end thereof to a power supply and diode-connected;

a second MOS transistor of the first conductivity type connected at a first end thereof to the power supply and connected at a second end thereof to a second end of the first MOS transistor, diode-connected, and connected in parallel with the first MOS transistor, the second MOS transistor having same size as the first MOS transistor does;

a memory cell connected between the second end of the first MOS transistor and ground, the memory cell capable of adjusting a current flowing through the memory cell;

a third MOS transistor of the first conductivity type connected at a first end thereof to the power supply, and diode-connected, the third MOS transistor having same size as the first MOS transistor does;

a fourth MOS transistor of the first conductivity type connected at a first end thereof to the power supply, connected at a second end thereof to a second end of the third MOS transistor, diode-connected, and connected in parallel with the third MOS transistor, the fourth MOS transistor having same size as the third MOS transistor does;

a fifth MOS transistor of a second conductivity type connected between the second end of the fourth MOS transistor and the ground and supplied at a gate thereof with the first reference voltage;

a sixth MOS transistor of the second conductivity type connected between the second end of the fourth MOS transistor and the ground and supplied at a gate thereof with the second reference voltage;

a first selection MOS transistor connected between the second end of the fourth MOS transistor and the fifth MOS transistor;

a second selection MOS transistor connected between the second end of the fourth MOS transistor and the sixth MOS transistor; and

an amplifier circuit which is supplied with a sense voltage at the second end of the first MOS transistor and a comparison voltage at the second end of the third MOS transistor in a state in which only either the first selection MOS transistor or the second selection MOS transistor is in an on-state, which compares the sense voltage with the comparison voltage, and which outputs a comparison result signal depending upon a result of the comparison.

### BRIEF DESCRIPTION OF THE DRAWINGS

FIG. 1 is a diagram showing an example of a circuit configuration of a semiconductor storage device (NOR flash memory) 100a which becomes a comparative example;

FIG. 2 is a diagram showing ideal cell current distribution in multi-value data memory cells and cell current distribution in multi-value data memory cells in the comparative example;

FIG. 3 is a diagram showing the source-drain current of a MOS transistor as a function of the area of the MOS transistor;

FIG. 4 is a circuit diagram showing a configuration of a principal part of a semiconductor storage device (NOR flash memory) 100 according to a first embodiment which is an aspect of the present invention;

FIG. 5 is a diagram showing an example of performance dispersion of a MOS transistor;

FIG. 6 is a diagram showing cell current distributions of memory cells of multi-value data in the first embodiment;

FIG. 7 is a circuit diagram showing an example of a principal part configuration of a semiconductor storage device 200 according to a second embodiment which is an aspect of the present invention;

FIG. 8 is a circuit diagram showing an example of a principal part configuration of a semiconductor storage device 300 according to a third embodiment which is an aspect of the present invention;

FIG. 9 is a circuit diagram showing an example of a principal part configuration of a semiconductor storage device 400 according to a fourth embodiment which is an aspect of the present invention;

FIG. 10 is a diagram showing relations among the cell current and the comparison current of the memory cell of multi-value data and the gate voltage of the memory cell;

FIG. 11 is a diagram showing relations among the cell current and the comparison current corresponding to multi-value data and temperature, in the comparative example;

FIG. 12 is a diagram showing relations among the cell current and the comparison current corresponding to multi-value data and temperature, in the fourth embodiment;

FIG. 13 is a cross-sectional view of an exemplary semiconductor chip (multi chip package: MCP) 120 incorporating the semiconductor storage apparatus (the NOR flash memories) 100 described in the embodiment 1 and another memory; and

FIG. 14 is a block diagram showing an exemplary internal configuration of a cellular phone of this type.

### DETAILED DESCRIPTION

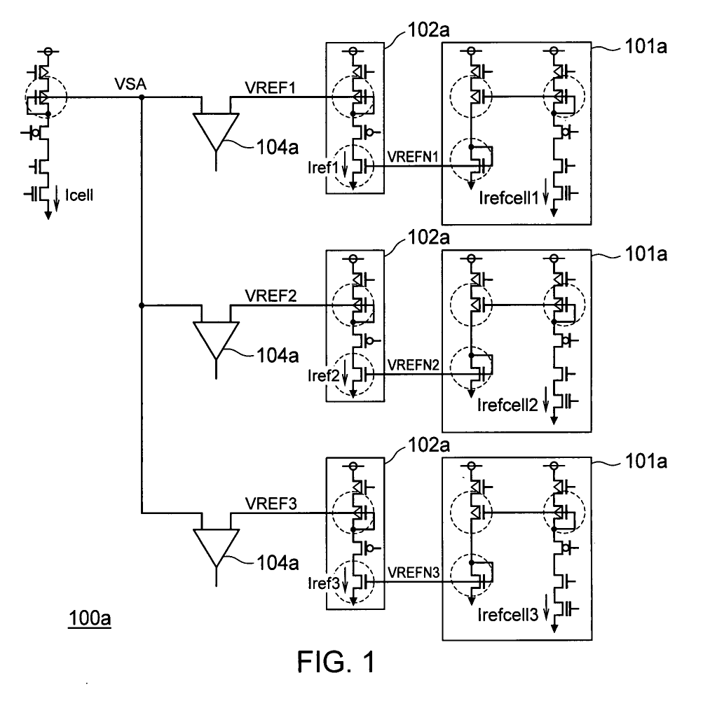

FIG. 1 is a diagram showing an example of a circuit configuration of a semiconductor storage device (NOR flash memory) 100a which becomes a comparative example.

As shown in FIG. 1, reference voltage sources 101a generate reference voltages VREFN1 to VREFN3 in response to reference cell currents Irefcell1 to Irefcell3 which flow through reference cells. Comparison voltage generation circuits 102a generate comparison currents Iref1 to Iref3 and comparison voltages VREF1 to VREF3 in response to the reference voltages VREFN1 to VREFN3.

Amplifier circuits 104a compare the comparison voltages VREF1 to VREF3 with a sense voltage VSA which depends upon a cell current Icell flowing through a memory cell, and output comparison result signals which depend upon results of the comparison.

The semiconductor storage device 100a reads multi-value data stored in memory cells based on the comparison result signals.

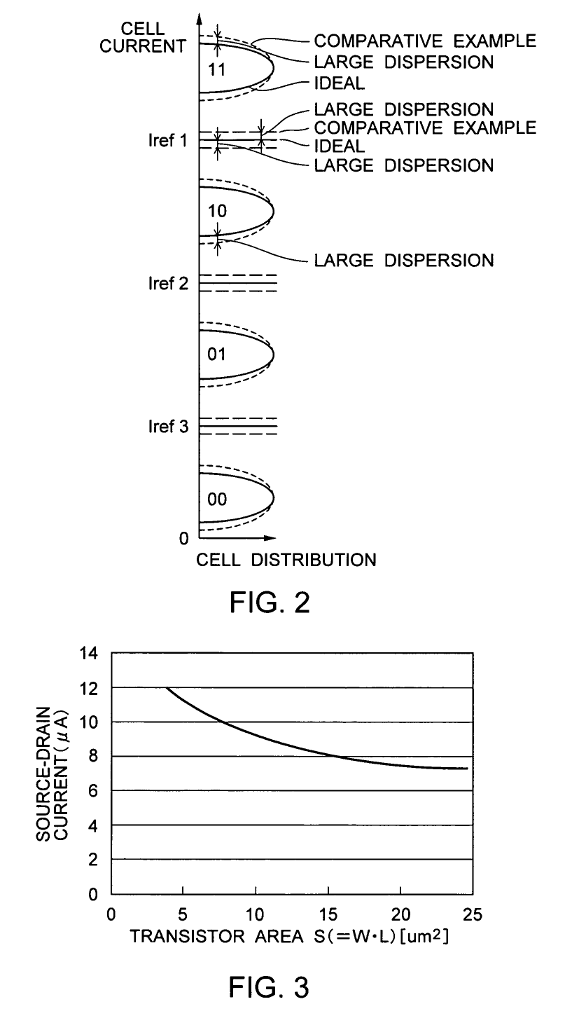

FIG. 2 is a diagram showing ideal cell current distribution in multi-value data memory cells and cell current distribution in multi-value data memory cells in the comparative example.

As shown in FIG. 2, cell current distribution is spread by dispersion of element performance in the cell current distribution in the comparative example as compared with the ideal cell current distribution. If it is necessary to arrange a plurality of cell current distributions in the current space as in a multi-value memory, then the spread of the cell current distribution has an evil effect on the multi-valuing trend.

FIG. 3 is a diagram showing the source-drain current of a MOS transistor as a function of the area of the MOS transistor.

It is known that the dispersion of the performance of the MOS transistor such as the source-drain current or the threshold voltage is in inverse proportion to the area (size) of the MOS transistor represented as S=L (channel length)·W (channel width).

Conventionally, therefore, for example, a technique for making the performance dispersion small by increasing L·W of MOS transistors each surrounded by a dashed line in the semiconductor storage device 100 shown in FIG. 1 is adopted.

In this technique, however, there is a limit in reduction of dispersion because dispersion σ for S=L·W is in the saturation trend even if S=L·W is made large.

In this way, the semiconductor storage device in the above-described comparative example has a problem that the cell current varies.

Hereafter, embodiments of a semiconductor storage device according to the present invention will be described more specifically with reference to the drawings in order to solve the above problem found by the applicant.

The embodiments will be described supposing that MOS transistors of first conductivity type are pMOS transistors and MOS transistors of second conductivity type are nMOS transistors.

However, similar operation may be implemented by changing the circuit polarity and using pMOS transistors as MOS transistors of first conductivity type and nMOS transistors as MOS transistors of second conductivity type.

### First Embodiment

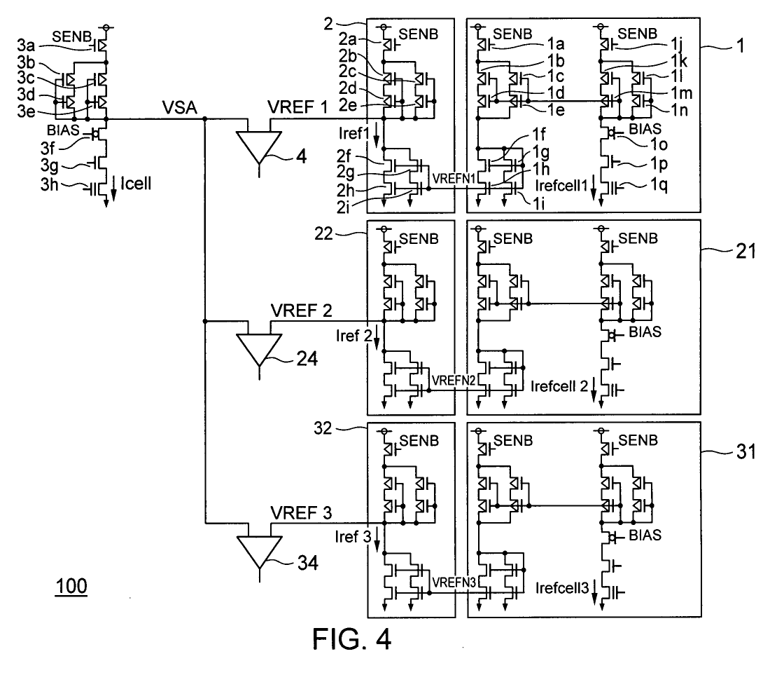

FIG. 4 is a circuit diagram showing a configuration of a principal part of a semiconductor storage device (NOR flash memory) 100 according to a first embodiment which is an aspect of the present invention.

As shown in FIG. 4, the semiconductor storage device 100 includes first to third reference voltage sources 1, 21 and 31, first to third comparison voltage generation circuits 2, 22 and 32, pMOS transistors 3a to 3e, nMOS transistors 3f and 3g, a memory cell 3h, and first to third amplifier circuits 4, 24 and 34.

The pMOS transistor 3a is connected at its source to a power supply. The pMOS transistor 3a is adapted to turn on when a voltage SENB is applied to its gate.

The pMOS transistor 3d is connected at its source to the power supply via the pMOS transistors 3a and 3b, and is diode-connected. Gates of the pMOS transistors 3d and 3b are connected together. The pMOS transistors 3b and 3d have the same size.

The pMOS transistor 3e is connected at its source to the power supply via the pMOS transistors 3a and 3c. Drains of the pMOS transistors 3e and 3d are connected together, and the pMOS transistor 3e is diode-connected. Gates of the pMOS transistors 3e and 3c are connected together. The pMOS transistors 3c and 3e have the same size. The pMOS transistor 3e is connected in parallel with the pMOS transistor 3d, and the pMOS transistor 3e has the same size as that of the pMOS transistor 3d.

The nMOS transistor 3f is connected at its drain to the drains of the pMOS transistors 3d and 3e. A threshold voltage of the nMOS transistor 3f is set so as to be in the neighborhood of 0 V, and a predetermined fixed voltage BIAS which is equal to at least the threshold voltage is applied to the nMOS transistor 3f at its gate.

The nMOS transistor 3g is connected at its gate to a column selection line (not shown), and the nMOS transistor 3g is adapted to be turned on in response to a signal applied to the column selection line.

The memory cell 3h is formed of, for example, a non-volatile transistor which can be adjusted in threshold voltage (for example, an EEPROM cell which can be adjusted in threshold value by injecting electrons into its floating gate or trapping electrons in a nitride film serving as a charge storage layer). The memory cell 3h is connected between second ends (drains) of the pMOS transistors 3d and 3e and ground via the nMOS transistors 3f and 3g. The cell current Icell flows through the memory cell 3h by applying a read voltage to its gate. In other words, the memory cell 3h can adjust the current flowing through itself.

The first reference voltage source 1 is adapted to generate a first reference voltage VREFN1 in response to a reference cell current Irefcell1. The first reference voltage source 1 includes pMOS transistors (reference MOS transistors) 1a to 1e and 1j to 1n, nMOS transistors (reference MOS transistors) 1f to 1i, nMOS transistors 1o and 1p, and a reference cell 1q.

The pMOS transistor 1a is connected at its source to the power supply. The pMOS transistor 1a is adapted to turn on when the voltage SENB is applied to its gate.

The pMOS transistor 1d is connected at its source to the power supply via the pMOS transistors 1a and 1b. Gates of the pMOS transistors 1d and 1b are connected together. The pMOS transistors 1b and 1d have the same size.

The pMOS transistor 1e is connected at its source to the power supply via the pMOS transistors 1a and 1c. Drains of the pMOS transistors 1e and 1d are connected together. Gates of the pMOS transistors 1e, 1c and 1d are connected together. The pMOS transistor is has the same size as that of the pMOS transistor 1e. The pMOS transistor 1e is connected in parallel with the pMOS transistor 1d, and the pMOS transistor 1e has the same size as that of the pMOS transistor 1d.

The nMOS transistor 1h is connected at its source to the drain of the pMOS transistors 1d via the nMOS transistor 1f, and diode-connected. Gates of the nMOS transistors 1h and 2h are connected together, and the nMOS transistor 1h has the same size as that of 2h. The nMOS transistor 1f has the same size as that of the nMOS transistor 1h. A gate voltage of the nMOS transistor 1h becomes a first reference voltage VREFN1.

The nMOS transistor 1i is connected between the drain of the pMOS transistor 1d and the ground in parallel with the nMOS transistor 1h, and diode-connected. The nMOS transistor 1i has the same size as that of the nMOS transistor 1h. The nMOS transistor 1g is connected between the nMOS transistor 1i and the pMOS transistors 1d. Gates of the nMOS transistors 1g and if are connected together. The nMOS transistor 1g has the same size as that of the nMOS transistor 1h.

The pMOS transistor 1j is connected at its source to the power supply. The pMOS transistor 1j is adapted to turn on when the voltage SENB is applied to its gate.

The pMOS transistor 1m is connected at its source to the power supply via the pMOS transistors 1j and 1k, and diode-connected. Gates of the pMOS transistors 1m, 1k and 1d are connected together. The pMOS transistor 1m and the pMOS transistors 1k have the same size.

The pMOS transistor 1n is connected at its source to the power supply via the pMOS transistors 1j and 1l. Drains of the pMOS transistors 1n and 1m are connected together. The pMOS transistor in is diode-connected. Gates of the pMOS transistors 1n and 1l are connected together. The pMOS transistor in and the pMOS transistors 1l have the same size. The pMOS transistor 1n is connected in parallel with the pMOS transistor 1m. The pMOS transistor in and the pMOS transistors 1m have the same size. Drains of the nMOS transistor 1o and the pMOS transistors 1m and in are connected together. A threshold voltage of the nMOS transistor 1o is set so as to be in the neighborhood of 0 V, and a predetermined fixed voltage BIAS which is equal to at least the threshold voltage is applied to the nMOS transistor 1o at its gate.

The nMOS transistor 1p is connected at its gate to a signal (not shown) which is activated at the time of read operation, and the nMOS transistor 1p is adapted to turn on in the read operation.

The reference cell 1q is formed of, for example, a non-volatile transistor which can be adjusted in threshold voltage (for example, an EEPROM cell which can be adjusted in threshold value by injecting electrons into its floating gate or trapping electrons in a nitride film serving as a charge storage layer). The reference cell 1q may be formed of a resistor element in which the reference cell current can be adjusted.

The reference cell 1q is connected between drains of the pMOS transistors 1m and 1n and the ground via the nMOS transistors 1o and 1p. The reference cell current Irefcell flows through the reference cell 1q by applying a voltage to its gate. In other words, the reference cell 1q can adjust the current flowing through itself.

The second reference voltage source 21 has a circuit configuration similar to that of the first reference voltage source 1. The second reference voltage source 21 is adapted to generate a second reference voltage VREFN2 which is lower than the first reference voltage VREFN1 in response to a reference cell current Irefcell2.

The third reference voltage source 31 has a circuit configuration similar to that of the first reference voltage source 1. The third reference voltage source 31 is adapted to generate a third reference voltage VREFN3 which is lower than the second reference voltage VREFN2, in response to a reference cell current Irefcell3.

A first comparison voltage generation circuit 2 is adapted to generate a first comparison voltage VREF1 in response to a comparison current Iref1 which flows in response to the first reference voltage VREFN1. The first comparison voltage generation circuit 2 includes nMOS transistors 2a to 2e and nMOS transistors 2f to 2i.

The pMOS transistor 2a is connected at its source to the power supply. The pMOS transistor 2a is adapted to turn on when the voltage SENB is applied to its gate.

The pMOS transistor 2d is connected at its source to the power supply via the pMOS transistors 2a and 2b, and diode-connected. Gates of the pMOS transistors 2d and 2b are connected together. The pMOS transistors 2d and 2b have the same size. The pMOS transistor 2d has the same size as the pMOS transistor 3d already described does.

The pMOS transistor 2e is connected at its source to the power supply via the pMOS transistors 2a and 2c. Drains of the pMOS transistors 2e and 2d are connected together. The pMOS transistor 2e is diode-connected. Gates of the pMOS transistors 2e, 2c and 2d are connected together. The pMOS transistors 2c and 2e have the same size. The pMOS transistor 2e is connected in parallel with the pMOS transistor 2d, and the pMOS transistor 2e has the same size as that of the pMOS transistor 2d.

The nMOS transistor 2h is connected at its source to the drain of the pMOS transistors 2d via the nMOS transistor 2f, connected at its gate to the gate of the nMOS transistor 1h, and diode-connected. In other words, the first reference voltage VREFN1 is applied to the gate of the nMOS transistor 2h. The nMOS transistor 2h has the same size as that of the nMOS transistor 1h. The nMOS transistor 2f has the same size as that of the nMOS transistor 2h.

The nMOS transistor 2i is connected between the drain of the pMOS transistor 2d and the ground in parallel with the nMOS transistor 2h, and diode-connected. The nMOS transistor 2i has the same size as that of the nMOS transistor 2h. The nMOS transistor 2g is connected between the nMOS transistor 2i and the pMOS transistors 2d. Gates of the nMOS transistors 2g and 2f are connected together. The nMOS transistor 2g has the same size as that of the nMOS transistor 2h.

The first comparison voltage generation circuit 2 having such a configuration outputs a voltage at the drain of the pMOS transistor 2d as the first comparison voltage VREF1 in response to the comparison current Iref1 which flows between the pMOS transistor 2d and the nMOS transistor 2f.

The second comparison voltage generation circuit 22 has a circuit configuration similar to that of the first comparison voltage generation circuit 2. The second comparison voltage generation circuit 22 is adapted to generate a second comparison voltage VREF2 in response to a comparison current Iref2 which flows in response to the second reference voltage VREFN2.

The third comparison voltage generation circuit 32 has a circuit configuration similar to that of the first comparison voltage generation circuit 2. The third comparison voltage generation circuit 32 is adapted to generate a third comparison voltage VREF3 in response to a comparison current Iref3 which flows in response to the third reference voltage VREFN3.

Incidentally, it is now supposed that the following relation holds true: comparison current Iref1>comparison current Iref2>comparison current Iref3.

The first amplifier circuit 4 is adapted to be supplied with a sense voltage VSA at the drain of the pMOS transistor 3d and the first comparison voltage VREF1 at the drain of the pMOS transistor 2d. The first amplifier circuit 4 compares the sense voltage VSA with the first comparison voltage VREF1, and outputs a first comparison result signal which depends upon a result of the comparison.

The second amplifier circuit 24 is adapted to be supplied with the sense voltage VSA and the second comparison voltage VREF2. The second amplifier circuit 24 compares the sense voltage VSA with the second comparison voltage VREF2, and outputs a second comparison result signal which depends upon a result of the comparison.

The third amplifier circuit 34 is adapted to be supplied with the sense voltage VSA and the third comparison voltage VREF3. The third amplifier circuit 34 compares the sense voltage VSA with the third comparison voltage VREF3, and outputs a third comparison result signal which depends upon a result of the comparison.

The semiconductor storage device 100 having the configuration described heretofore conducts read operation, write operation, and verify operation on multi-value data stored in the memory cell 3h based on the first to third comparison result signals.

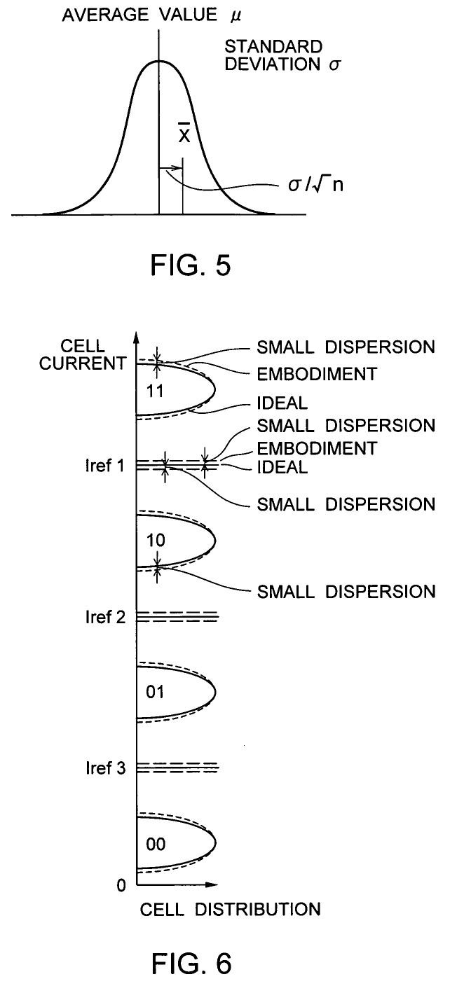

FIG. 5 is a diagram showing an example of performance dispersion of a MOS transistor. FIG. 6 is a diagram showing cell current distributions of memory cells of multi-value data in the first embodiment.

If sample averages X based on random samples having a magnitude n follow a distribution having an average μ and a standard deviation a, then the sample averages X get closer to normal distribution having an average μ and a standard deviation σ/√n as shown in FIG. 5 according to the central limiting theorem.

In other words, the influence of the dispersion of the performance of the MOS transistor can be reduced by dividing one MOS transistor into a plurality of parts.

Since the semiconductor storage device 100 includes a plurality of pMOS transistors 3b to 3e as already described, the influence of the performance dispersion of the MOS transistor on the cell current Icell can be reduced (FIG. 6).

In the same way, each of the first to third comparison voltage generation circuits 2, 22 and 32 includes a plurality of MOS transistors. Therefore, the influence of the performance dispersion of the MOS transistor on the comparison currents Iref1 to Iref3 can be reduced (FIG. 6).

In this way, the semiconductor storage device 100 conducts the verify operation based on the cell current Icell and the comparison currents Iref1 to Iref3 which are reduced in influence of performance dispersion of the MOS transistor. As a result, the distribution of the cell current corresponding to multi-value data can get closer to the ideal distribution (FIG. 6).

The first to third comparison voltage generation circuits 2, 22 and 32 generate the comparison currents Iref1 to Iref3, respectively. Therefore, dispersion directions of the comparison currents Iref1 to Iref3 do not jointly move.

In the semiconductor storage device according to the present embodiment, dispersion of the cell current can be reduced as heretofore described.

### Second Embodiment

In the first embodiment, dispersion directions of the comparison currents Iref1 to Iref3 do not jointly move as already described. In some cases, therefore, the spacing between adjacent comparison currents becomes narrow. In this case, the spacing between adjacent cell current distributions becomes narrow. In some cases, therefore, it becomes difficult to set multi-value data.

For example, if the comparison current Iref1 varies in a direction in which it becomes small in FIG. 6, then the distribution of the cell current corresponding to data “10” to be written shifts in a downward direction because of the relation to the comparison current Iref1. On the other hand, if the comparison current Iref2 varies in a direction in which it becomes large, then the distribution of the cell current corresponding to data “01” to be written shifts in an upward direction because of the relation to the comparison current Iref2.

As a result, the spacing between the cell current distribution corresponding to the data “10” and the cell current distribution corresponding to the data “01” becomes narrow.

In the present second embodiment, therefore, a configuration for making multi-value data setting advantageous by moving the dispersion directions of the comparison currents Iref1 to Iref3 jointly will now be described.

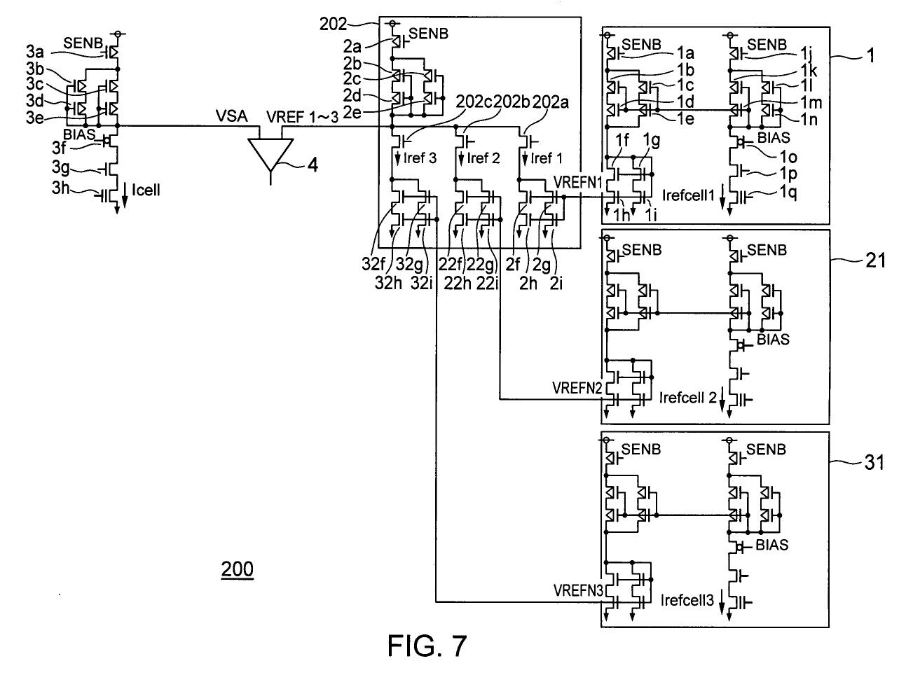

FIG. 7 is a circuit diagram showing an example of a principal part configuration of a semiconductor storage device 200 according to a second embodiment which is an aspect of the present invention. Components denoted by the same characters as those in the first embodiment are components like those in the first embodiment.

As shown in FIG. 7, the semiconductor storage device 200 includes first to third reference voltage sources 1, 21 and 31, a comparison voltage generation circuit 202, pMOS transistors 3a to 3e, nMOS transistors 3f and 3g, a memory cell 3h, and an amplifier circuit 4.

The comparison voltage generation circuit 202 is adapted to be supplied with first to third reference voltages VREFN1 to VREFN3 respectively generated by first to third reference voltage sources 1, 21 and 31. The remaining configuration of the semiconductor storage device 200 is the same as that of the semiconductor storage device 100 in the first embodiment.

The comparison voltage generation circuit 202 is adapted to generate first to third comparison voltages VREF1 to VREF3 in response to comparison currents Iref1 to Iref3 which flow in response to the first to third reference voltage VREFN1 to VREFN3, respectively. As compared with the first comparison voltage generation circuit 2 in the first embodiment, the comparison voltage generation circuit 202 further includes nMOS transistors 22f to 22i and 32f to 32i and nMOS transistors (selection MOS transistors) 202a to 202c.

The nMOS transistors 22f to 22i are connected in the same way as the nMOS transistors 2f to 2i except that the second reference voltage VREFN2 is applied to the nMOS transistor 22h at its gate.

The nMOS transistors 32f to 32i are connected in the same way as the nMOS transistors 2f to 2i except that the third reference voltage VREFN3 is applied to the nMOS transistor 32h at its gate.

The nMOS transistor 202a is connected between drains of a pMOS transistor 2d and the nMOS transistor 2f.

The nMOS transistor 202b is connected between drains of the pMOS transistor 2d and the nMOS transistor 22f.

The nMOS transistor 202c is connected between drains of the pMOS transistor 2d and the nMOS transistor 32f.

The comparison voltage generation circuit 202 outputs a voltage at the drain of the pMOS transistor 2d which depends upon the comparison current Iref1 flowing between the pMOS transistor 2d and the nMOS transistor 2f in the state in which only the nMOS transistor 202a is in the on-state, as the first comparison voltage VREF1.

The comparison voltage generation circuit 202 outputs a voltage at the drain of the pMOS transistor 2d which depends upon the comparison current Iref2 flowing between the pMOS transistor 2d and the nMOS transistor 22f in the state in which only the nMOS transistor 202b is in the on-state, as the second comparison voltage VREF2.

The comparison voltage generation circuit 202 outputs a voltage at the drain of the pMOS transistor 2d which depends upon the comparison current Iref3 flowing between the pMOS transistor 2d and the nMOS transistor 32f in the state in which only the nMOS transistor 202c is in the on-state, as the third comparison voltage VREF3.

Incidentally, it is now supposed that the following relation holds true: comparison current Iref1>comparison current Iref2>comparison current Iref3.

The amplifier circuit 4 is supplied with a sense voltage VSA and the first comparison voltage VREF1 in the state in which only the nMOS transistor 202a is in the on-state. The amplifier circuit 4 compares the sense voltage VSA with the first comparison voltage VREF1, and outputs a first comparison result signal which depends upon a result of the comparison.

The amplifier circuit 4 is supplied with the sense voltage VSA and the second comparison voltage VREF2 in the state in which only the nMOS transistor 202b is in the on-state. The amplifier circuit 4 compares the sense voltage VSA with the second comparison voltage VREF2, and outputs a second comparison result signal which depends upon a result of the comparison.

The amplifier circuit 4 is supplied with the sense voltage VSA and the third comparison voltage VREF3 in the state in which only the nMOS transistor 202c is in the on-state. The amplifier circuit 4 compares the sense voltage VSA with the third comparison voltage VREF3, and outputs a third comparison result signal which depends upon a result of the comparison.

The semiconductor storage device 200 having the configuration described heretofore conducts read operation, write operation, and verify operation on multi-value data stored in the memory cell 3h based on the first to third comparison result signals.

In the comparison voltage generation circuit 202, the comparison currents Iref1 to Iref3 flow through pMOS transistors 2b to 2e. In other words, influences of performance dispersion of the pMOS transistors 2b to 2e on the comparison currents Iref1 to Iref3 are the same.

In the semiconductor storage device 200, therefore, directions in which the comparison currents Iref1 to Iref3 vary become easier in moving jointly as compared with the first embodiment. As a result, it becomes easier to set multi-value data.

Since the semiconductor storage device 200 includes a plurality of pMOS transistors 3b to 3e in the same way as the first embodiment, the influence of the performance dispersion of the MOS transistor on the cell current Icell can be reduced.

In the semiconductor storage device according to the present embodiment, dispersion of the cell current can be reduced as heretofore described.

### Third Embodiment

In the present third embodiment, an example of a configuration for reducing the circuit area will now be described.

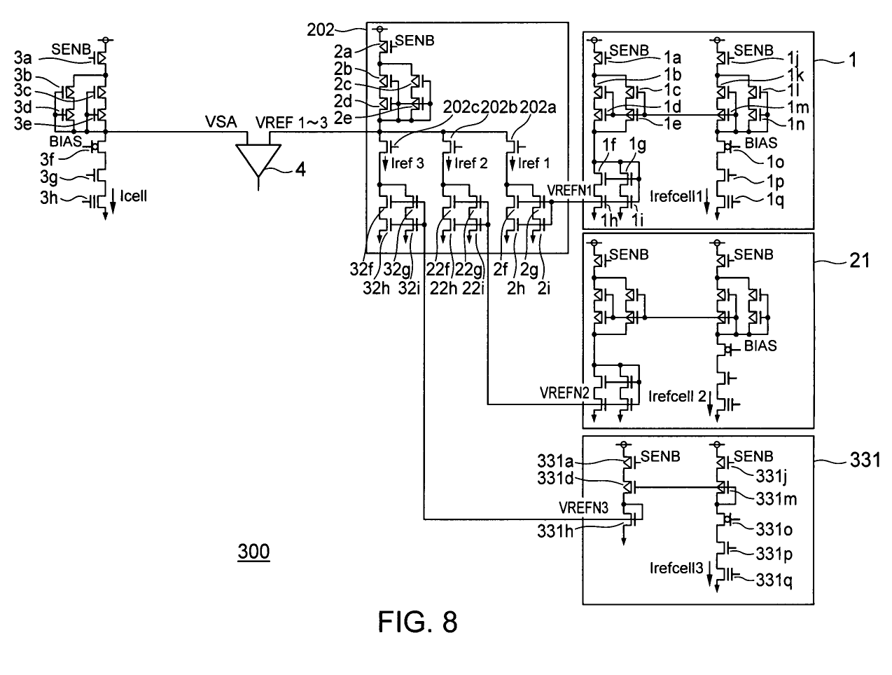

FIG. 8 is a circuit diagram showing an example of a principal part configuration of a semiconductor storage device 300 according to a third embodiment which is an aspect of the present invention. Components denoted by the same characters as those in the first and second embodiments are components like those in the first and second embodiments.

As shown in FIG. 8, the semiconductor storage device 300 includes first to third reference voltage sources 1, 21 and 331, a comparison voltage generation circuit 202, pMOS transistors 3a to 3e, nMOS transistors 3f and 3g, a memory cell 3h, and an amplifier circuit 4.

The third reference voltage source 331 in the semiconductor storage device 300 differs in circuit configuration from the third reference voltage source 31 in the semiconductor storage device 200 in the second embodiment. The remaining configuration of the semiconductor storage device 300 is the same as that of the semiconductor storage device 200 in the second embodiment.

The third reference voltage source 331 is adapted to generate a third reference voltage VREFN3 in response to a reference cell current Irefcell3. The third reference voltage source 331 includes pMOS transistors (reference MOS transistors) 331a, 331d, 331j and 331m, an nMOS transistor (reference MOS transistor) 331h, nMOS transistors 3310 and 331p, and a reference cell 331q.

The pMOS transistor 331a is connected at its source to a power supply. The pMOS transistor 331a is adapted to turn on by application of a voltage SENB.

The pMOS transistor 331d is connected at its source to the power supply via the pMOS transistor 331a.

The nMOS transistor 331h is connected at its source to the nMOS transistor 331d at its drain, and diode-connected. Gates of the nMOS transistor 331h and the nMOS transistor 32h are connected together. The nMOS transistor 331h and the nMOS transistor 32h have the same size. A gate voltage of the nMOS transistor 331h becomes a third reference VREFN3.

The pMOS transistor 331j is connected at its source to the power supply. The pMOS transistor 331j is adapted to turn on by application of the voltage SENB.

The pMOS transistor 331m is connected at its source to the power supply via the pMOS transistor 331j, and diode-connected. Gates of the pMOS transistor 331m and the pMOS transistor 331d are connected together.

Drains of the nMOS transistor 3310 and the pMOS transistor 331m are connected together. A threshold voltage of the nMOS transistor 331o is set so as to be in the neighborhood of 0 V, and a predetermined fixed voltage BIAS which is equal to at least the threshold voltage is applied to the nMOS transistor 331o at its gate.

The nMOS transistor 331p is connected at its gate to a signal (not shown) activated at the time of read operation, and the nMOS transistor 331p is adapted to turn on in the read operation.

The reference cell 331q is formed of, for example, a non-volatile transistor which can be adjusted in threshold voltage. The reference cell 331q may be formed of a resistor element in which the reference cell current can be adjusted.

The reference cell 331q is connected between the drain of the pMOS transistor 331m and the ground via the nMOS transistors 331o and 331p. The reference cell current Irefcell3 flows through the reference cell 331q by applying a voltage to its gate. In other words, the reference cell 331q can adjust the current flowing through itself.

A comparison current Iref3 is smaller than comparison currents Iref1 and Iref2, and influence of performance dispersion of the MOS transistor thereon is small. The third reference voltage VREFN3 for generating the comparison current Iref3 may vary as compared with the first and second reference voltages VREFN1 and VREFN2. As for the third reference voltage source 331 for generating the third reference voltage VREFN3, therefore, the nMOS transistor is not divided as shown in FIG. 8.

As a result, the circuit area of the semiconductor storage device 300 can be made small.

In the semiconductor storage device 300, therefore, directions in which the comparison currents Iref1 to Iref3 vary become easier in moving jointly as compared with the first embodiment in the same way as the second embodiment. As a result, it becomes easier to set multi-value data.

Since the semiconductor storage device 300 includes a plurality of pMOS transistors 3b to 3e in the same way as the first embodiment, the influence of the performance dispersion of the MOS transistor on the cell current Icell can be reduced.

In the semiconductor storage device according to the present embodiment, dispersion of the cell current can be reduced as heretofore described.

### Fourth Embodiment

In the present fourth embodiment, an example of a configuration for adjusting temperature characteristics of the reference cell current will now be described.

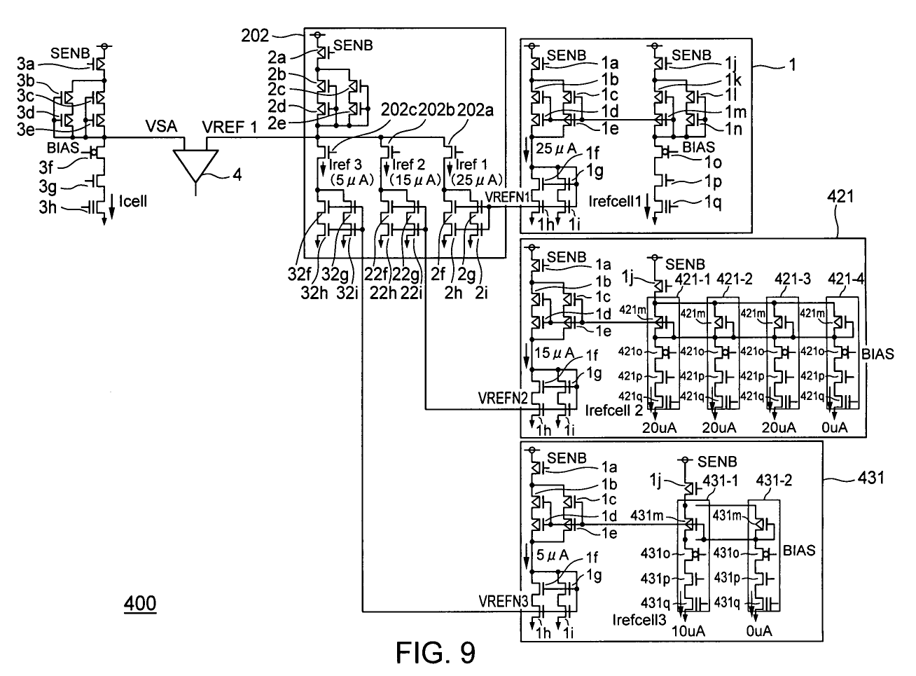

FIG. 9 is a circuit diagram showing an example of a principal part configuration of a semiconductor storage device 400 according to a fourth embodiment which is an aspect of the present invention. Components denoted by the same characters as those in the first and second embodiments are components like those in the first and second embodiments.

As shown in FIG. 9, the semiconductor storage device 400 includes first to third reference voltage sources 1, 421 and 431, a comparison voltage generation circuit 202, pMOS transistors 3a to 3e, nMOS transistors 3f and 3g, a memory cell 3h, and an amplifier circuit 4.

The second and third reference voltage sources 421 and 431 in the semiconductor storage device 400 differ in circuit configuration from the second and third reference voltage sources 21 and 31 in the semiconductor storage device 200 in the second embodiment. The remaining configuration of the semiconductor storage device 400 is the same as that of the semiconductor storage device 200 in the second embodiment.

In the first reference voltage source 1, the first reference voltage VREFN1 is generated in response to a value (25 μA) of a current which flows between a pMOS transistor 1d and an nMOS transistor if. In the comparison voltage generation circuit 202, a comparison current Iref1 (25 μA) flows in response to the first reference voltage VREFN1.

The second reference voltage source 421 is adapted to generate a second reference voltage VREFN2 in response to a reference cell current Irefcell2. The second reference voltage source 421 includes pMOS transistors (reference MOS transistors) 1a to 1e and 1j, nMOS transistors (reference MOS transistors) 1f to 1i, and a plurality of reference circuits 421-1 to 421-4.

The reference circuit 421-1 includes a pMOS transistor 421m, nMOS transistors 421o and 421p and a reference cell 421q.

The pMOS transistor 421m is connected at its source to the power supply via the pMOS transistor 1j, and diode-connected.

Gates of the pMOS transistor 421m and the pMOS transistor 421d are connected together.

Drains of the nMOS transistor 421o and the pMOS transistor 421m are connected together. A threshold voltage of the nMOS transistor 421o is set so as to be in the neighborhood of 0 V, and a predetermined fixed voltage BIAS which is equal to at least the threshold voltage is applied to the nMOS transistor 421o at its gate.

The nMOS transistor 421p is connected at its gate to a signal (not shown) activated at the time of read operation, and the nMOS transistor 421p is adapted to turn on in the read operation.

The reference cell 421q is formed of, for example, a non-volatile transistor which can be adjusted in threshold voltage. The reference cell 421q may be formed of a resistor element in which the reference cell current can be adjusted.

The reference cell 421q is connected between the drain of the pMOS transistor 421m and the ground via the nMOS transistors 421o and 421p. A current flows through the reference cell 421q by applying a voltage to its gate. In other words, the reference cell 421q can adjust the current flowing through itself.

Each of other reference circuits 421-2 to 421-4 also has a circuit configuration similar to that of the reference circuit 421-1.

In the second reference voltage source 421, a current which flows through the reference cell 421q in the reference circuits 421-1 to 421-3 has a value of 20 μA, which is set so as to be larger than a current (15 μA) flowing between the pMOS transistor 1d and the nMOS transistor 1f. In addition, in the second reference voltage source 421, a value of a current which flows through the reference cell 421q in the remaining reference circuit 421-4 is set equal to 0 A.

A value obtained by dividing a sum (60 μA) of currents flowing through the reference cells 421q in the reference circuits 421-1 to 421-4 by the number (four) of the reference circuits 421-1 to 421-4 is equal to the value (15 μA) of the current flowing between the pMOS transistor 1d and the nMOS transistor 1f.

In the second reference voltage source 421, a second reference voltage VREFN2 is generated in response to the value (15 μA) of the current flowing between the pMOS transistor 1d and the nMOS transistor 1f. In the comparison voltage generation circuit 202, a comparison current Iref2 (15 μA) flows in response to the second reference voltage VREFN2.

The third reference voltage source 431 is adapted to generate a third reference voltage VREFN3 in response to a reference cell current Irefcell3. The third reference voltage source 431 includes pMOS transistors (reference MOS transistors) 1a to 1e and 1j, nMOS transistors (reference MOS transistors) 1f to 1i, and a plurality of reference circuits 431-1 and 432-2.

The reference circuit 431-1 includes a pMOS transistor 431m, nMOS transistors 431o and 431p and a reference cell 431q.

The pMOS transistor 431m is connected at its source to the power supply via the pMOS transistor 1j, and diode-connected. Gates of the pMOS transistor 431m and the pMOS transistor 1d are connected together.

Drains of the nMOS transistor 431o and the pMOS transistor 431m are connected together. A threshold voltage of the nMOS transistor 431o is set so as to be in the neighborhood of 0 V, and a predetermined fixed voltage BIAS which is equal to at least the threshold voltage is applied to the nMOS transistor 4310 at its gate.

The nMOS transistor 431p is connected at its gate to a signal (not shown) activated at the time of read operation, and the nMOS transistor 431p is adapted to turn on in the read operation.

The reference cell 431q is formed of, for example, a non-volatile transistor which can be adjusted in threshold voltage. The reference cell 431q may be formed of a resistor element in which the reference cell current can be adjusted.

The reference cell 431q is connected between the drain of the pMOS transistor 431m and the ground via the nMOS transistors 431o and 431p. A current flows through the reference cell 431q by applying a voltage to its gate. In other words, the reference cell 431q can adjust the current flowing through itself.

The other reference circuit 431-2 also has a circuit configuration similar to that of the reference circuit 431-1.

In the third reference voltage source 431, a current which flows through the reference cell 431q in the reference circuit 431-1 has a value of 10 μA, which is set so as to be larger than a current (5 μA) flowing between the pMOS transistor id and the nMOS transistor if. In addition, in the third reference voltage source 431, a value of a current which flows through the reference cell 431q in the other reference circuit 431-2 is set equal to 0 A.

A value obtained by dividing a sum (10 μA) of currents flowing through the reference cells 431q in the reference circuits 431-1 and 431-2 by the number (two) of the reference circuits 431-1 and 431-2 is equal to the value (5 μA) of the current flowing between the pMOS transistor 1d and the nMOS transistor 1f.

In the third reference voltage source 431, a third reference voltage VREFN3 is generated in response to the value (5 μA) of the current flowing between the pMOS transistor 1d and the nMOS transistor 1f. In the comparison voltage generation circuit 202, a comparison current Iref3 (5 μA) flows in response to the third reference voltage VREFN3.

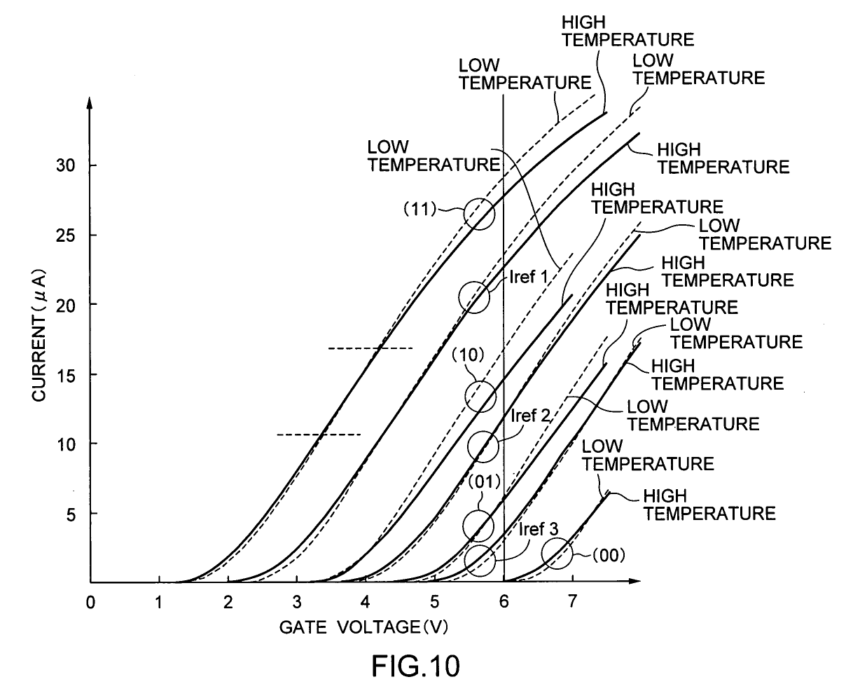

FIG. 10 is a diagram showing relations among the cell current and the comparison current of the memory cell of multi-value data and the gate voltage of the memory cell. Incidentally, the reference cell current of the reference cell assumes the same tendency as that of the cell current of the memory cell.

As shown in FIG. 10, there is a tendency of temperature characteristics in which the cell current (corresponding to multi-value data “11”) increases at low temperatures, in the vicinity of read voltage (6 V). There is a similar tendency in the comparison current Iref1 as well.

In a region having a middle current, there is a tendency of temperature characteristics in which the cell current (corresponding to multi-value data “10”) does not change, in the vicinity of read voltage (6 V). At low temperatures, however, there is a tendency of temperature characteristics in which the comparison current Iref2 decreases.

In a region having a small current, there is a tendency of temperature characteristics in which the cell current (corresponding to multi-value data “01”) decreases at low temperatures, in the vicinity of read voltage (6 V). At low temperatures, there is a tendency of temperature characteristics in which the comparison current Iref3 decreases.

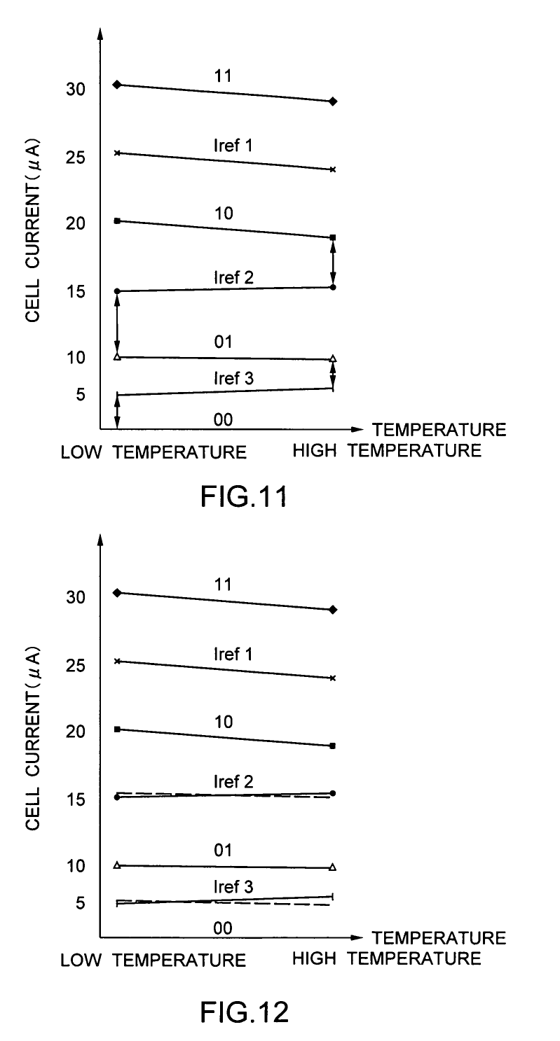

FIG. 11 is a diagram showing relations among the cell current and the comparison current corresponding to multi-value data and temperature, in the comparative example.

If the cell current becomes small, temperature characteristics of the cell current differ from temperature characteristics of the comparison currents Iref2 and Iref3 in the comparative example as shown in FIG. 11. In this case, it becomes difficult to set desired cell current distribution corresponding to desired multi-value data.

FIG. 12 is a diagram showing relations among the cell current and the comparison current corresponding to multi-value data and temperature, in the fourth embodiment.

In the second reference voltage source 421, the current of 20 μA is let flow through each of the three reference cells 421q, and the current which flows through one reference cell 421Q is set equal to 0 A, as already described. As a result, temperature characteristics of the current (15 μA) which flows between the pMOS transistor 1d and the nMOS transistor if can be brought closer to temperature characteristics in the case where the current of 20 μA flows through one reference cell. In other words, temperature characteristics of the comparison current Iref2 gets closer to temperature characteristics in the case where the current of 20 μA flows through one reference cell (FIG. 12).

In the third reference voltage source 431, a current of 10 μA is let flow through one reference cell 431q and the current which flows through the other reference cell 431q is set equal to 0 A. As a result, temperature characteristics of the current (5 μA) which flows between the pMOS transistor 1d and the nMOS transistor if can be brought closer to temperature characteristics in the case where the current of 10 μA flows through one reference cell. In other words, temperature characteristics of the comparison current Iref3 gets closer to temperature characteristics in the case where the current of 10 μA flows through one reference cell (FIG. 12).

As a result, the temperature characteristics of the cell current and the temperature characteristics of the comparison current which are close in current value get close to each other. Even if the temperature changes, therefore, it is possible to set desired cell current distribution corresponding to desired multi-value data.

In the semiconductor storage device 400, directions in which the comparison currents Iref1 to Iref3 vary become easier in moving jointly as compared with the first embodiment in the same way as the second embodiment. As a result, it becomes easier to set multi-value data.

Since the semiconductor storage device 400 includes a plurality of pMOS transistors 3b to 3e in the same way as the first embodiment, the influence of the performance dispersion of the MOS transistor on the cell current Icell can be reduced.

In the semiconductor storage device according to the present embodiment, dispersion of the cell current can be reduced as heretofore described.

### Application Embodiment

The application of the semiconductor storage apparatus (the NOR flash memories) 100 to 400 according to the embodiments described above is not particularly limited, and the NOR flash memories 100 to 400 can be used as a storage device for various types of electric or electronic apparatus. In addition, the NOR flash memories 100 to 400 can be housed in the same package as another memory, such as a NAND flash memory. In the following, a case in which the semiconductor storage apparatus (the NOR flash memories) 100 according to the embodiment 1 is used will be described. However, the semiconductor storage apparatus (the NOR flash memories) according to the embodiments 2 to 4 can also be used in the same way.

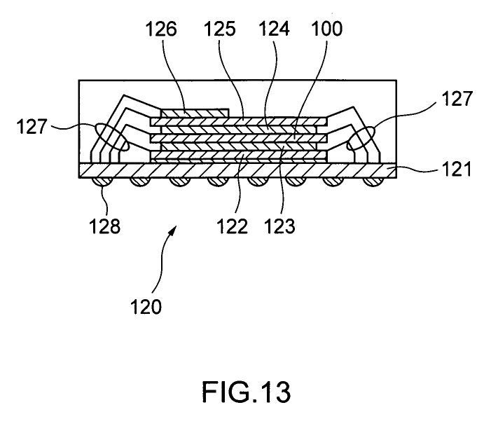

FIG. 13 is a cross-sectional view of an exemplary semiconductor chip (multi chip package: MCP) 120 incorporating the semiconductor storage apparatus (the NOR flash memories) 100 described in the embodiment 1 and another memory.

As shown in FIG. 13, the semiconductor chip 120 has a substrate 121, and a NAND flash memory 122, a spacer 123, the NOR flash memory 100, a spacer 124, a pseudo static random access memory (PSRAM) 125 and a controller 126 stacked in this order on a substrate 121, which are incorporated in the same package.

The NAND flash memory 122 has a plurality of memory cells capable of storing multivalued data, for example. Alternatively, the semiconductor chip 120 may have a synchronous dynamic random access memory (SDRAM) instead of the PSRAM.

Of the memories described above, depending on the use by the memory system, the NAND flash memory 122 is used as a data storing memory, for example. The NOR flash memory 100 is used as a program storing memory, for example. The PSRAM 125 is used as a work memory, for example.

The controller 126 primarily controls input/output of data to/from the NAND flash memory 122 and manages data in the NAND flash memory 122. The controller 126 has an ECC correcting circuit (not shown), and adds an error-correcting code (ECC) in data writing and performs analysis and processing of an error-correcting code in data reading.

The NAND flash memory 122, the NOR flash memory 100, the PSRAM 125 and the controller 126 are bonded to the substrate 121 by a wire 127.

Each solder ball 128 formed on the back surface of the substrate 121 is electrically connected to the corresponding wire 127. For example, the package is a surface-mounted ball grid array (BGA) in which the solder balls 128 are two-dimensionally arranged.

Next, a case where the semiconductor chip 120 described above is used in a cellular phone, which is an example of the electronic apparatus, will be described.

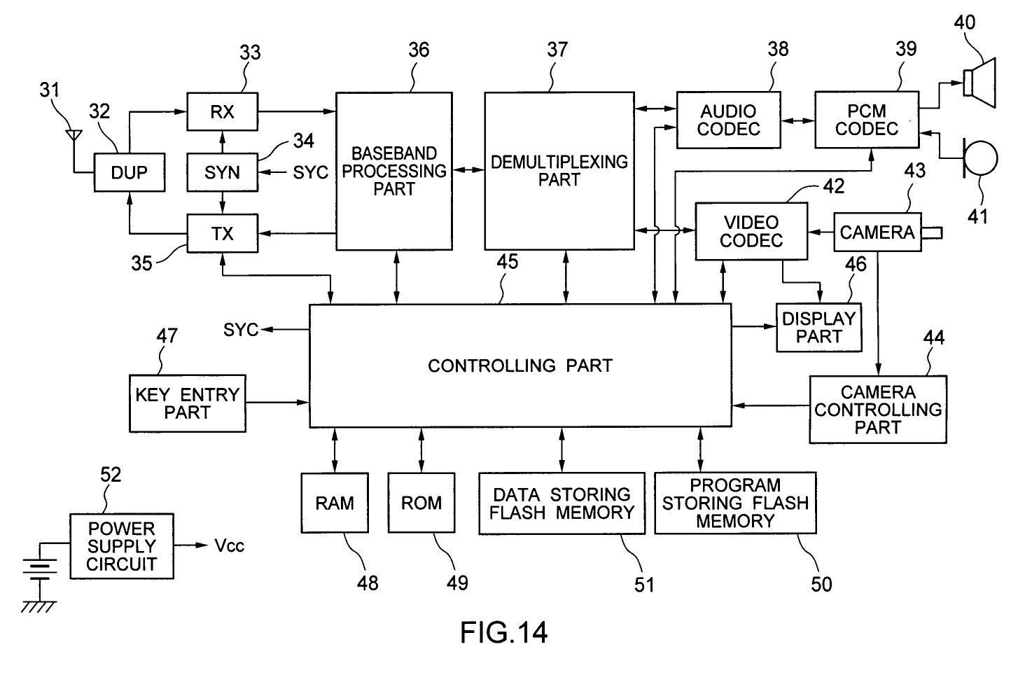

FIG. 14 is a block diagram showing an exemplary internal configuration of a cellular phone of this type. The cellular phone shown in FIG. 14 has an antenna 31, an antenna duplexer 32 that switches between transmission and reception signals, a receiving circuit 33 that converts a radio signal into a baseband signal, a frequency synthesizer 34 that generates a local oscillation signal for transmission and reception, a transmitting circuit 35 that generates a radio signal by modulating a transmission signal, a baseband processing part 36 that generates a reception signal of a predetermined transmission format based on the base band signal, a demultiplexing part 37 that separates the reception signal into audio, video and text data, an audio codec 38 that decodes the audio data into a digital audio signal, a PCM codec 39 that PCM-decodes the digital audio signal to generates an analog audio signal, a speaker 40, a microphone 41, a video codec 42 that decodes the video data into a digital video signal, a camera 43, a camera controlling part 44, a controlling part 45 that controls the whole of the cellular phone, a display part 46, a key entry part 47, a RAM 48, a ROM 49, a program storing flash memory 50, a data storing flash memory 51 and a power supply circuit 52.

In FIG. 14, the program storing flash memory 50 is the NOR flash memory 100 according to the embodiment 1 described above, and the data storing flash memory 51 is the NAND flash memory 22.

From the above description, those skilled in the art will appreciate additional advantages and be able to devise various modifications. Therefore, the aspects of the present invention are not limited to the embodiments specifically described above. Various additions, modifications, and partial omissions are possible without departing from the concept and spirit of the present invention, which are derived from the contents defined by the claims and equivalents thereto.

What is claimed is:

1. A semiconductor storage device comprising:
a first reference voltage source which generates a first reference voltage;
a first MOS transistor of a first conductivity type connected at a first end thereof to a power supply and diode-connected;
a second MOS transistor of the first conductivity type connected at a first end thereof to the power supply and connected at a second end thereof to a second end of the first MOS transistor, diode-connected, and connected in parallel with the first MOS transistor, the second MOS transistor having same size as the first MOS transistor does;
a memory cell connected between the second end of the first MOS transistor and ground, the memory cell capable of adjusting a current flowing through the memory cell;
a third MOS transistor of the first conductivity type connected at a first end thereof to the power supply, and diode-connected, the third MOS transistor having same size as the first MOS transistor does;
a fourth MOS transistor of the first conductivity type connected at a first end thereof to the power supply, connected at a second end thereof to a second end of the third MOS transistor, diode-connected, and connected in parallel with the third MOS transistor, the fourth MOS transistor having same size as the third MOS transistor does;
a fifth MOS transistor of a second conductivity type connected between the second end of the fourth MOS transistor and the ground and supplied at a gate thereof with the first reference voltage; and
an amplifier circuit which is supplied with a sense voltage at the second end of the first MOS transistor and a comparison voltage at the second end of the third MOS transistor, which compares the sense voltage with the comparison voltage, and which outputs a comparison result signal depending upon a result of the comparison.

2. The semiconductor storage device according to claim 1, further comprising a sixth MOS transistor of the second conductivity type connected between the second end of the fourth MOS transistor and the ground, connected in parallel with the fifth MOS transistor, and supplied at a gate thereof with the first reference voltage, the sixth MOS transistor having same size as the fifth MOS transistor does.

3. The semiconductor storage device according to claim 1, further comprising:
a seventh MOS transistor connected between the second of the first MOS transistor and the power supply, and connected at a gate thereof to the gate of the first MOS transistor, the seventh MOS transistor having same size as the first MOS transistor does;
an eighth MOS transistor connected between the second of the second MOS transistor and the power supply, and connected at a gate thereof to the gate of the second MOS transistor, the eighth MOS transistor having same size as the second MOS transistor does;
a ninth MOS transistor connected between the second of the third MOS transistor and the power supply, and connected at a gate thereof to the gate of the third MOS transistor, the ninth MOS transistor having same size as the third MOS transistor does;
a tenth MOS transistor connected between the second of the fourth MOS transistor and the power supply, and connected at a gate thereof to the gate of the fourth MOS transistor, the tenth MOS transistor having same size as the fourth MOS transistor does.

4. The semiconductor storage device according to claim 2, further comprising:
a seventh MOS transistor connected between the second of the first MOS transistor and the power supply, and connected at a gate thereof to the gate of the first MOS transistor, the seventh MOS transistor having same size as the first MOS transistor does;
an eighth MOS transistor connected between the second of the second MOS transistor and the power supply, and connected at a gate thereof to the gate of the second MOS transistor, the eighth MOS transistor having same size as the second MOS transistor does;
a ninth MOS transistor connected between the second of the third MOS transistor and the power supply, and connected at a gate thereof to the gate of the third MOS transistor, the ninth MOS transistor having same size as the third MOS transistor does;
a tenth MOS transistor connected between the second of the fourth MOS transistor and the power supply, and connected at a gate thereof to the gate of the fourth MOS transistor, the tenth MOS transistor having same size as the fourth MOS transistor does.

5. The semiconductor storage device according to claim 1,
wherein the second reference voltage source comprises:
a first reference MOS transistor of the first conductivity type connected at a first end thereof to the power supply and diode-connected;
a second reference MOS transistor of the first conductivity type connected at a first end thereof to the power supply, connected at a second end thereof to a second end of the first reference MOS transistor, diode-connected, and connected in parallel with the first reference MOS transistor, the second reference MOS transistor having same size as the first reference MOS transistor does;
a first reference cell connected between a second end of the first reference MOS transistor and the ground, the first reference cell being capable of adjusting a current which flows through the first reference cell;
a third reference MOS transistor of the first conductivity type connected at a first end thereof to the power supply, connected at a gate thereof to a gate of the first reference MOS transistor, the third reference MOS transistor having same size as the first reference MOS transistor does;
a fourth reference MOS transistor of the first conductivity type connected at a first end thereof to the power supply, connected at a second end thereof to a second end of the third reference MOS transistor, and connected in parallel with the third reference MOS transistor, the fourth reference MOS transistor having same size as the first reference MOS transistor does;
a fifth reference MOS transistor of the second conductivity type connected between a second of the third reference MOS transistor and the ground, diode-connected, and connected at a gate thereof to the gate of the fifth MOS transistor, the fifth reference MOS transistor having same size as the fifth MOS transistor does;
a sixth reference MOS transistor of the second conductivity type connected between the second end of the third reference MOS transistor and the ground in parallel with the fifth reference MOS transistor, diode-connected, and connected at a gate thereof to the gate of the fifth MOS transistor, the sixth reference MOS transistor having same size as the fifth reference MOS transistor does.

6. The semiconductor storage device according to claim 2,
wherein the second reference voltage source comprises:
a first reference MOS transistor of the first conductivity type connected at a first end thereof to the power supply and diode-connected;
a second reference MOS transistor of the first conductivity type connected at a first end thereof to the power supply, connected at a second end thereof to a second end of the first reference MOS transistor, diode-connected, and connected in parallel with the first reference MOS transistor, the second reference MOS transistor having same size as the first reference MOS transistor does;
a first reference cell connected between a second end of the first reference MOS transistor and the ground, the first reference cell being capable of adjusting a current which flows through the first reference cell;
a third reference MOS transistor of the first conductivity type connected at a first end thereof to the power supply, connected at a gate thereof to a gate of the first reference MOS transistor, the third reference MOS transistor having same size as the first reference MOS transistor does;
a fourth reference MOS transistor of the first conductivity type connected at a first end thereof to the power supply, connected at a second end thereof to a second end of the third reference MOS transistor, and connected in parallel with the third reference MOS transistor, the fourth reference MOS transistor having same size as the first reference MOS transistor does;
a fifth reference MOS transistor of the second conductivity type connected between a second of the third reference MOS transistor and the ground, diode-connected, and connected at a gate thereof to the gate of the fifth MOS transistor, the fifth reference MOS transistor having same size as the fifth MOS transistor does;
a sixth reference MOS transistor of the second conductivity type connected between the second end of the third reference MOS transistor and the ground in parallel with the fifth reference MOS transistor, diode-connected, and connected at a gate thereof to the gate of the fifth MOS transistor, the sixth reference MOS transistor having same size as the fifth reference MOS transistor does.

7. The semiconductor storage device according to claim 3,
wherein the second reference voltage source comprises:
a first reference MOS transistor of the first conductivity type connected at a first end thereof to the power supply and diode-connected;
a second reference MOS transistor of the first conductivity type connected at a first end thereof to the power supply, connected at a second end thereof to a second end of the first reference MOS transistor, diode-connected, and connected in parallel with the first reference MOS transistor, the second reference MOS transistor having same size as the first reference MOS transistor does;
a first reference cell connected between a second end of the first reference MOS transistor and the ground, the first reference cell being capable of adjusting a current which flows through the first reference cell;
a third reference MOS transistor of the first conductivity type connected at a first end thereof to the power supply, connected at a gate thereof to a gate of the first reference MOS transistor, the third reference MOS transistor having same size as the first reference MOS transistor does;
a fourth reference MOS transistor of the first conductivity type connected at a first end thereof to the power supply, connected at a second end thereof to a second end of the third reference MOS transistor, and connected in parallel with the third reference MOS transistor, the fourth reference MOS transistor having same size as the first reference MOS transistor does;
a fifth reference MOS transistor of the second conductivity type connected between a second of the third reference MOS transistor and the ground, diode-connected, and connected at a gate thereof to the gate of the fifth MOS transistor, the fifth reference MOS transistor having same size as the fifth MOS transistor does;
a sixth reference MOS transistor of the second conductivity type connected between the second end of the third reference MOS transistor and the ground in parallel with the fifth reference MOS transistor, diode-connected, and connected at a gate thereof to the gate of the fifth MOS transistor, the sixth reference MOS transistor having same size as the fifth reference MOS transistor does.

8. The semiconductor storage device according to claim 1, wherein the semiconductor storage device reads data stored in the memory cell based on the comparison result signals.

9. The semiconductor storage device according to claim 2, wherein the semiconductor storage device reads data stored in the memory cell based on the comparison result signals.

10. The semiconductor storage device according to claim 3, wherein the semiconductor storage device reads data stored in the memory cell based on the comparison result signals.

11. The semiconductor storage device according to claim 4, wherein the semiconductor storage device reads data stored in the memory cell based on the comparison result signals.

12. The semiconductor storage device according to claim 5, wherein the semiconductor storage device reads data stored in the memory cell based on the comparison result signals.

13. The semiconductor storage device according to claim 1, wherein the semiconductor storage device is a NOR flash memory.

14. A semiconductor storage device comprising:
a first reference voltage source which generates a first reference voltage;
a second reference voltage source which generates a second reference voltage which is lower than the first reference voltage;
a first MOS transistor of a first conductivity type connected at a first end thereof to a power supply and diode-connected;
a second MOS transistor of the first conductivity type connected at a first end thereof to the power supply and connected at a second end thereof to a second end of the first MOS transistor, diode-connected, and connected in parallel with the first MOS transistor, the second MOS transistor having same size as the first MOS transistor does;
a memory cell connected between the second end of the first MOS transistor and ground, the memory cell capable of adjusting a current flowing through the memory cell;
a third MOS transistor of the first conductivity type connected at a first end thereof to the power supply, and diode-connected, the third MOS transistor having same size as the first MOS transistor does;
a fourth MOS transistor of the first conductivity type connected at a first end thereof to the power supply, connected at a second end thereof to a second end of the third MOS transistor, diode-connected, and connected in parallel with the third MOS transistor, the fourth MOS transistor having same size as the third MOS transistor does;
a fifth MOS transistor of a second conductivity type connected between the second end of the fourth MOS transistor and the ground and supplied at a gate thereof with the first reference voltage;
a sixth MOS transistor of the second conductivity type connected between the second end of the fourth MOS transistor and the ground and supplied at a gate thereof with the second reference voltage;
a first selection MOS transistor connected between the second end of the fourth MOS transistor and the fifth MOS transistor;
a second selection MOS transistor connected between the second end of the fourth MOS transistor and the sixth MOS transistor; and
an amplifier circuit which is supplied with a sense voltage at the second end of the first MOS transistor and a comparison voltage at the second end of the third MOS transistor in a state in which only either the first selection MOS transistor or the second selection MOS transistor is in an on-state, which compares the sense voltage with the comparison voltage, and which outputs a comparison result signal depending upon a result of the comparison.

15. The semiconductor storage device according to claim 14,
wherein the first reference voltage source comprises:
a first reference MOS transistor of the first conductivity type connected at a first end thereof to the power supply and diode-connected;
a second reference MOS transistor of the first conductivity type connected at a first end thereof to the power supply, connected at a second end thereof to a second end of the first reference MOS transistor, diode-connected, and connected in parallel with the first reference MOS transistor, the second reference MOS transistor having same size as the first reference MOS transistor does;
a first reference cell connected between a second end of the first reference MOS transistor and the ground, the first reference cell being capable of adjusting a current which flows through the first reference cell;
a third reference MOS transistor of the first conductivity type connected at a first end thereof to the power supply, connected at a gate thereof to a gate of the first reference MOS transistor, the third reference MOS transistor having same size as the first reference MOS transistor does;
a fourth reference MOS transistor of the first conductivity type connected at a first end thereof to the power supply, connected at a second end thereof to a second end of the third reference MOS transistor, and connected in parallel with the third reference MOS transistor, the fourth reference MOS transistor having same size as the first reference MOS transistor does;
a fifth reference MOS transistor of the second conductivity type connected between a second of the third reference MOS transistor and the ground, diode-connected, and connected at a gate thereof to the gate of the fifth MOS transistor, the fifth reference MOS transistor having same size as the fifth MOS transistor does; and
a sixth reference MOS transistor of the second conductivity type connected between the second end of the third reference MOS transistor and the ground in parallel with the fifth reference MOS transistor, diode-connected, and connected at a gate thereof to the gate of the fifth MOS transistor, the sixth reference MOS transistor having same size as the fifth reference MOS transistor does,
wherein the second reference voltage source comprises:
a seventh reference MOS transistor of the first conductivity type connected at a first end thereof to the power supply and diode-connected;
a second reference cell connected between a second end of the seventh reference MOS transistor and the ground, the second reference cell being capable of adjusting a current which flows through the second reference cell;
an eighth reference MOS transistor of the first conductivity type connected at a first end thereof to the power supply, connected at a gate thereof to a gate of the seventh reference MOS transistor, the eighth reference MOS transistor having same size as the seventh reference MOS transistor does; and
a ninth reference MOS transistor of the second conductivity type connected between a second of the eighth reference MOS transistor and the ground, diode-connected, and connected at a gate thereof to the gate of the sixth transistor, the ninth reference MOS transistor having same size as the sixth MOS transistor does.

16. The semiconductor storage device according to claim 14,
wherein the first reference voltage source comprises:
a first reference MOS transistor of the first conductivity type connected at a first end thereof to the power supply and diode-connected;
a second reference MOS transistor of the first conductivity type connected at a first end thereof to the power supply, connected at a second end thereof to a second end of the first reference MOS transistor, diode-connected, and connected in parallel with the first reference MOS transistor, the second reference MOS transistor having same size as the first reference MOS transistor does;
a first reference cell connected between a second end of the first reference MOS transistor and the ground, the first reference cell being capable of adjusting a current which flows through the first reference cell;
a third reference MOS transistor of the first conductivity type connected at a first end thereof to the power supply, connected at a gate thereof to a gate of the first reference MOS transistor, the third reference MOS transistor having same size as the first reference MOS transistor does;
a fourth reference MOS transistor of the first conductivity type connected at a first end thereof to the power supply, connected at a second end thereof to a second end of the third reference MOS transistor, and connected in parallel with the third reference MOS transistor, the fourth reference MOS transistor having same size as the first reference MOS transistor does;
a fifth reference MOS transistor of the second conductivity type connected between a second of the third reference MOS transistor and the ground, diode-connected, and connected at a gate thereof to the gate of the fifth MOS transistor, the fifth reference MOS transistor having same size as the fifth MOS transistor does; and
a sixth reference MOS transistor of the second conductivity type connected between the second end of the third reference MOS transistor and the ground in parallel with the fifth reference MOS transistor, diode-connected, and connected at a gate thereof to the gate of the fifth MOS transistor, the sixth reference MOS transistor having same size as the fifth reference MOS transistor does,
wherein the second reference voltage source comprises:
a seventh reference MOS transistor of the first conductivity type connected at a first end thereof to the power supply and diode-connected to form a reference circuit;
a second reference cell connected between a second end of the seventh reference MOS transistor and the ground to form the reference circuit, the second reference cell being capable of adjusting a current which flows through the second reference cell;
an eighth reference MOS transistor of the first conductivity type connected at a first end thereof to the power supply, and connected at a gate thereof to a gate of the seventh reference MOS transistor, the eighth reference MOS transistor having same size as the seventh reference MOS transistor does;
a ninth reference MOS transistor of the first conductivity type connected at a first end thereof to the power supply, connected at a second end thereof to a second end of the eighth reference MOS transistor, and connected in parallel with the eighth reference MOS transistor, the ninth reference MOS transistor having same size as the seventh reference MOS transistor does;
a tenth reference MOS transistor of the second conductivity type connected between a second of the eighth reference MOS transistor and the ground, diode-connected, and connected at a gate thereof to the gate of the sixth transistor, the tenth reference MOS transistor having same size as the sixth MOS transistor does; and
a eleventh reference MOS transistor of the second conductivity type connected between the second end of the eighth reference MOS transistor and the ground in parallel with the tenth reference MOS transistor, and diode-connected, the eleventh reference MOS transistor having same size as the tenth reference MOS transistor does,
wherein
the second reference voltage source includes a plurality of the reference circuits,
a current flowing through the second reference cell in some of the reference circuits is set so as to be larger than a current flowing between the eighth reference MOS transistor and the tenth reference MOS transistor,
a value of a current flowing through the second reference cell in a remaining reference circuit is set equal to 0 A, and a value obtained by dividing a sum of currents flowing through the second reference cells in all of the reference circuits by the number of all of the reference circuits is equal to a value of a current flowing between the eighth reference MOS transistor and the tenth reference MOS transistor.

17. The semiconductor storage device according to claim 14, wherein the semiconductor storage device reads data stored in the memory cell based on the comparison result signals.

18. The semiconductor storage device according to claim 15, wherein the semiconductor storage device reads data stored in the memory cell based on the comparison result signals.

19. The semiconductor storage device according to claim 16, wherein the semiconductor storage device reads data stored in the memory cell based on the comparison result signals.

20. The semiconductor storage device according to claim 14, wherein the semiconductor storage device is a NOR flash memory.
